(19) United States
(12) Patent Application Publication
(10) Pub. No.: US 2007/0133641 A1
(43) Pub. Date: Jun. 14, 2007

(54) SURFACE-EMITTING TYPE SEMICONDUCTOR LASER AND METHOD FOR MANUFACTURING THE SAME

(75) Inventor: Tsuyoshi KANEKO, Suwa-shi, Nagano-ken (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/567,428

(22) Filed: Dec. 6, 2006

(30) Foreign Application Priority Data
Dec. 13, 2005 (JP) 2005-358569

(51) Int. Cl. H01S 5/00

(52) U.S. Cl. 372/50.124

(57) ABSTRACT

A surface-emitting type semiconductor laser includes an upper mirror, a lower mirror, and an active layer disposed between the upper mirror and the lower mirror, and emits laser light in a direction of lamination of the lower mirror, the active layer and the upper layer, wherein at least one of the upper mirror and the lower mirror is in contact with the active layer, and includes a first region formed with a first semiconductor layer having a first refractive index, a second semiconductor layer having a second refractive index, and a third semiconductor layer provided between the first semiconductor layer and the second semiconductor layer and having a refractive index between the first refractive index and the second refractive index, and a second region formed with the first semiconductor layer and the second semiconductor layer alternately laminated.

The entire disclosure of Japanese Patent Application No. 2005-358569, filed Dec. 13, 2005 is expressly incorporated by reference herein.

### BACKGROUND

1. Technical Field

The present invention relates to surface-emitting type semiconductor lasers that emit laser light and methods for manufacturing the same.

2. Related Art

A typical surface-emitting type semiconductor laser has a basic structure in which a lower mirror composed of a semiconductor multilayer film, an active layer and an upper mirror composed of a semiconductor multilayer film are successively laminated. A resonator is formed by the lower mirror and the upper mirror, and the active layer is disposed inside the resonator. A surface-emitting type semiconductor laser having the structure described above emits laser light in a direction in which the layers are laminated. Compared to typical edge-emitting type semiconductor lasers that use parallel cleavage surfaces of a substrate as a resonator, the surface-emitting type semiconductor laser has various favorable characteristics. For example, surface-emitting type semiconductor lasers are suitable for mass-production, capable of direct modulation, capable of operation with low threshold levels, capable of oscillation in a single longitudinal mode, and a two-dimensional laser array structure can be readily formed with surface-emitting type semiconductor lasers.

Distributed Bragg reflection type mirrors (DBR) composed of alternately laminated two kinds of semiconductor layers of different refractive indexes are often used as the upper mirror and the lower mirror provided in the surface-emitting type semiconductor laser. When AlGaAs system material is used to form DBRs, two kinds of semiconductor layers whose aluminum (Al) and gallium (Ga) compositions are different from each other are used.

The surface-emitting type semiconductor laser has a structure in which the active layer is disposed in the resonator layer composed of the upper mirror and the lower mirror, as described above, such that electric current needs to be supplied to the active layer through the DBR. The DBR has high resistance due to energy barriers at interfaces of the laminated semiconductor layers of different kinds. Japanese patent 2646799 describes a technology to reduce the resistance of DBR by forming graded index layers (GI layers) whose composition gradually changes between semiconductor layers composing the DBR.

Also, the surface-emitting type semiconductor laser is provided with a current constricting layer near the active layer for controlling the path of current flowing through the active layer, and therefore often formed in a mesa structure in order to form the current constricting layer. In other words, the surface-emitting type semiconductor laser may often be provided with a structure in a columnar configuration formed by etching the upper mirror, the active layer and a portion of the lower mirror. Japanese translated patent application JP-T-2003-522421 describes an example of a surface-emitting type semiconductor laser of a mesa structure.

When GI layers described in Japanese patent 2646799 are formed between the two kinds of semiconductor layers having different refractive indexes composing the DBR in order to reduce the resistance of the DBR, changes in the refractive index between the semiconductor layers become gentler, which lowers the reflection coefficient compared to the structure in which GI layers are not formed (wherein changes in the refractive index between the semiconductor layers are steep). When a mirror having GI layers formed therein is used as the upper mirror or the lower mirror described above, optical power that accumulates in the resonator would lower, which may cause an elevation in the oscillation threshold of the surface-emitting type semiconductor laser.

To prevent an elevation in the oscillation threshold while using a mirror with GI layers formed therein, the number of laminated layers of the upper mirror or the lower mirror (the number of pairs of two different kinds of semiconductor layers) may be increased, to thereby compensate for the reduction in the reflection coefficient which is caused by the GI layers formed. However, when the number of laminated layers of the upper mirror or the lower mirror is increased, the amount of crystal growth is increased, which leads to deterioration of the crystallinity and lowers the performance of the surface-emitting type semiconductor laser. Also, when the amount of crystal growth is increased, the cost increases, and the tact time (the processing time necessary for forming the mirrors) also increases.

### SUMMARY

In accordance with an advantage of some aspects of the present invention, there are provided surface-emitting type semiconductor lasers with excellent performance such as low resistance and low oscillation threshold, and methods for manufacturing surface-emitting type semiconductor lasers which can manufacture the surface-emitting type semiconductor lasers at low costs without lowering the yield.

In accordance with an embodiment of the invention, a surface-emitting type semiconductor laser includes an upper mirror, a lower mirror, an active layer disposed between the upper mirror and the lower mirror, which emits laser light in a direction of lamination of the lower mirror, the active layer and the upper layer, wherein at least one of the upper mirror and the lower mirror includes a first region which is in contact with the active layer and is formed with a first semiconductor layer having a first refractive index, a second semiconductor layer having a second refractive index, and a third semiconductor layer provided between the first semiconductor layer and the second semiconductor layer and having a refractive index between the first refractive index and the second refractive index a second region formed with the first semiconductor layer and the second semiconductor layer.

It is noted that alternately laminating the first semiconductor layer and the second semiconductor layer means that the first semiconductor layer and the second semiconductor layer are laminated in contact with each other, and no other semiconductor layer is present between the first semiconductor layer and the second semiconductor layer. Also, the third semiconductor layer is not limited to a layer having a constant composition, but includes a layer having a graded composition (GI layer).

According to the embodiment described above, at least one of the upper mirror formed above the active layer and the lower mirror formed below the active layer is provided in a region contacting the active layer with a first region formed with a first semiconductor layer having a first refractive index, a second semiconductor layer having a second refractive index, and a third semiconductor layer provided between the first semiconductor layer and the second semiconductor layer and having a refractive index between the first refractive index and the second refractive index, and a second region formed with the first semiconductor layer and the second semiconductor layer alternately laminated, such that the resistance can be reduced.

The surface-emitting type semiconductor laser in accordance with an aspect of the embodiment of the invention may have a plurality of the first semiconductor layers and the second semiconductor layers formed in the first region, and the third semiconductor layer may preferably be formed at each of interfaces between the first semiconductor layers and the second semiconductor layers.

Also, in the surface-emitting type semiconductor laser in accordance with an aspect of the embodiment of the invention, at least one of the upper mirror and the lower mirror may be quipped with a third region having a mirror composed of a dielectric multilayer film.

According to the embodiment described above, the surface-emitting type semiconductor laser may be quipped with the third region in which a mirror composed of a dielectric multilayer film is formed. For this reason, even when a reflection coefficient lowers in the first region, a higher reflection coefficient is maintained in the third region other than the first region, such that a substantial reduction in the reflection coefficient of the upper mirror and the lower mirror can be prevented. As a result, a substantial elevation in the oscillation threshold of the surface-emitting type semiconductor laser is not caused.

Also, the surface-emitting type semiconductor laser in accordance with an aspect of the embodiment of the invention may be quipped with an electrode that is in contact with one of the first semiconductor layer and the second semiconductor layer composing the first region and supplies electric current to the active layer.

According to the embodiment described above, the electrode that supplies electric current to the active layer is in contact with one of the first semiconductor layer and the second semiconductor layer composing the first region that is a low resistance region, such that the oscillation threshold can be lowered.

Also, in the surface-emitting type semiconductor laser in accordance with an aspect of the embodiment of the invention, the one of the first semiconductor layer and the second semiconductor layer that is in contact with the electrode may have an impurity concentration higher than that of the other semiconductor layer.

According to the embodiment described above, because the semiconductor layer having a high impurity concentration is in contact with the electrode, sufficient ohmic contact can be obtained. Also, high adhesion with the electrode can be obtained.

Also, in the surface-emitting type semiconductor laser in accordance with an aspect of the embodiment of the invention, the electrode may include a first electrode provided at the first region of the upper mirror, and a second electrode provided at the first region of the lower mirror.

According to the embodiment described above, the first electrode that is one of the electrodes is provided at the first region of the upper mirror, and the second electrode that is the other electrode is provided at the first region of the lower mirror. As a result, energy barriers at interfaces of laminated semiconductor layers of different types are hardly present on the current flow path within the surface-emitting type semiconductor laser, which is particularly preferable in lowering the resistance.

Furthermore, in the surface-emitting type semiconductor laser in accordance with an aspect of the embodiment of the invention, the second electrode may contact one of the first semiconductor layer and the second semiconductor layer forming one of the first pair through fifth pair of the first semiconductor layer and the second semiconductor layer, the first pair being formed at an uppermost layer of the lower mirror.

According to the embodiment described above, the second electrode may contact one of the first semiconductor layer and the second semiconductor layer forming one of the first pair through fifth pair of the first semiconductor layer and the second semiconductor layer, the first pair being formed at the uppermost layer of the lower mirror located below the active layer. In other words, the second electrode is in contact with one of the semiconductor layers disposed at a position very close to the active layer, which is preferable in reducing the resistance.

Also, in the surface-emitting type semiconductor laser in accordance with an aspect of the embodiment of the invention, the upper mirror, the active layer and at least a part of the first region provided in the lower mirror may be formed in a columnar configuration to define a columnar section.

In the surface-emitting type semiconductor laser in accordance with an aspect of the embodiment of the invention, the semiconductor layers of the lower mirror located above the semiconductor layer that is in contact with the second electrode may be formed in the columnar section.

According to the embodiment described above, the upper mirror, the active layer and at least a portion of the first region provided in the lower mirror, in other words, the semiconductor layers located above the semiconductor layer that is in contact with the second electrode, form a columnar section. As described above, it is desirable for the second electrode to be in contact with a semiconductor layer disposed at a position very close to the active layer as much as possible in view of reducing the resistance. However, when the surface-emitting type semiconductor laser is formed to be in a columnar configuration, stress may be generated at the base portion of the columnar section, thereby causing cracks at the base portion. Therefore, if the active layer is disposed at the base portion, the device characteristics may be deteriorated. For this reason, by forming the semiconductor layers located above the semiconductor layer that is in contact with the second electrode in a columnar section, and by contacting the second electrode with one of the first semiconductor layer and the second semiconductor layer forming one of the first through fifth pair of the first semiconductor layer and the second semiconductor layer in which the first pair is formed at the uppermost layer of the lower mirror, the resistance can be reduced and the deterioration described above can be prevented.

Also, in the surface-emitting type semiconductor laser in accordance with an aspect of the embodiment of the invention, the first semiconductor layer and the second semiconductor layer may be composed of mixed crystal semiconductors of different compositions.

Furthermore, in the surface-emitting type semiconductor laser in accordance with an aspect of the embodiment of the invention, the first semiconductor layer may be composed of mixed crystal semiconductor with a lower composition than that of the second semiconductor layer.

A method for manufacturing a surface-emitting type semiconductor laser in accordance with another embodiment of the invention pertains to a method for manufacturing a surface-emitting type semiconductor laser including an upper mirror, a lower mirror and an active layer disposed between the upper mirror and the lower mirror, which emits laser light in a direction of lamination of the lower mirror, the active layer and the upper layer, and the method includes, in forming the upper mirror and the lower mirror, the steps of: forming, in at least one of the upper mirror and the lower mirror, a first region that is in contact with the active layer and includes a first semiconductor layer having a first refractive index, a second semiconductor layer having a second refractive index, and a third semiconductor layer provided between the first semiconductor layer and the second semiconductor layer and having a refractive index between the first refractive index and the second refractive index; and forming a second region formed with the first semiconductor layer and the second semiconductor layer alternately laminated in a region other than the first region.

According to the embodiment described above, when forming the upper mirror above the active layer and when forming the lower mirror below the active layer, a first region that is a region in close proximity to the active layer and has a first semiconductor layer having a first refractive index, a second semiconductor layer having a second refractive index, and a third semiconductor layer provided between the first semiconductor layer and the second semiconductor layer and having a refractive index between the first refractive index and the second refractive index, and a second region formed with the first semiconductor layer and the second semiconductor layer alternately laminated, are formed in at least one of the upper mirror and the lower mirror, whereby the resistance can be reduced.

The method for manufacturing a surface-emitting type semiconductor laser in accordance with an aspect of the embodiment of the invention may include the step of forming a third region having a mirror composed of a dielectric multilayer film in at least one of the upper mirror and the lower mirror.

According to the embodiment described above, the third region in which the first semiconductor layer and the second semiconductor layer are alternately laminated is formed in at least one of the upper mirror and the lower mirror. For this reason, even when the reflection coefficient lowers in the first region, a higher reflection coefficient is maintained in the third region, such that a substantial reduction in the reflection coefficient of the upper mirror and the lower mirror can be prevented. As a result, a substantial elevation in the oscillation threshold of the surface-emitting type semiconductor laser is not caused.

The method for manufacturing a surface-emitting type semiconductor laser in accordance with an aspect of the embodiment of the invention may include the step of etching the upper mirror, the active layer and the lower mirror to an inside of the first region formed in the lower mirror to form a columnar section composed of the upper mirror, the active layer and at least a portion of the lower mirror in a columnar configuration.

In the method for manufacturing a surface-emitting type semiconductor laser in accordance with an aspect of the embodiment of the invention, the first semiconductor layer and the second semiconductor layer may be composed of mixed crystals of different compositions, and when the upper mirror, the active layer and a portion inside the first region formed in the lower mirror are etched, the amount of etching is controlled while monitoring changes in the compositions.

According to the embodiment described above, when the upper mirror, the active layer and a portion inside the first region of the lower mirror are etched, the amount of etching is controlled while monitoring changes in the compositions, such that a desired one of the first semiconductor layer and the second semiconductor layer in the first region can be exposed.

### BRIEF DESCRIPTION OF THE DRAWINGS

FIG. 1 is a schematic cross-sectional view of a surface-emitting type semiconductor laser in accordance with an embodiment of the invention.

FIG. 2 is an enlarged cross-sectional view of a first mirror 11 and a second mirror 13 near an active layer 12.

FIG. 3 is a graph for describing changes in the reflection coefficients depending on the presence or absence of GI layers.

FIG. 4 is a cross-sectional view schematically showing a step of a method for manufacturing a surface-emitting type semiconductor laser in accordance with an embodiment of the invention.

FIG. 5 is a cross-sectional view schematically showing a step of the method for manufacturing a surface-emitting type semiconductor laser in accordance with the embodiment of the invention.

FIG. 6 is a cross-sectional view schematically showing a step of the method for manufacturing a surface-emitting type semiconductor laser in accordance with the embodiment of the invention.

FIG. 7 is a cross-sectional view schematically showing a step of the method for manufacturing a surface-emitting type semiconductor laser in accordance with the embodiment of the invention.

### DESCRIPTION OF EXEMPLARY EMBODIMENTS

A surface-emitting type semiconductor laser and a method for manufacturing the same in accordance with preferred embodiments of the invention are described below with reference to the accompanying drawings. The embodiments described below show a part of embodiments of the invention, and do not limit the invention, and changes can be optionally made within the scope of the invention. Also, in the drawings referred to below for describing the invention, the scale may be changed for each of the layers and each of the members so that the layers and the members can have appropriate sizes that can be recognized on the drawings.

Surface-Emitting Type Semiconductor Laser

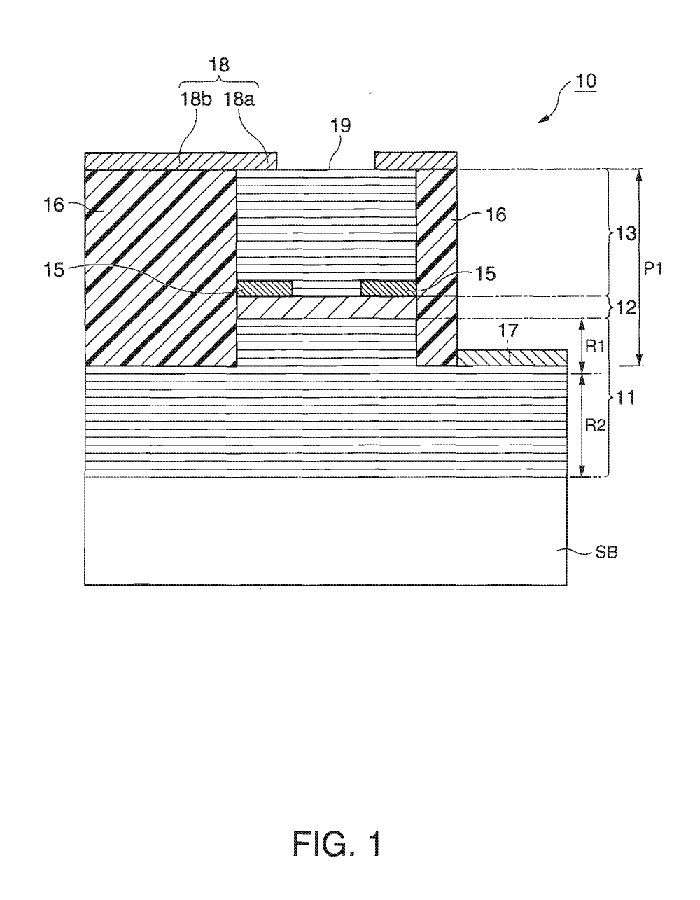

FIG. 1 is a schematic cross-sectional view of a surface-emitting type semiconductor laser 10 in accordance with an embodiment of the invention. As shown in FIG. 1, the surface-emitting type semiconductor laser 10 is formed on a semiconductor substrate (e.g., an n-type GaAs substrate in the present embodiment) SB. The surface-emitting type semiconductor laser 10 includes a vertical resonator. In accordance with the present embodiment, one of distributed reflection type multilayer mirrors (second mirror) 13, an active layer 12 and a portion of the other distributed reflection type multilayer mirror (first mirror) 11 that form the vertical resonator are formed in a columnar semiconductor deposited body (hereafter referred to as a columnar section) P1. In other words, the surface-emitting type semiconductor laser 10 has a structure in which a part thereof is included in the columnar section P1.

The surface-emitting type semiconductor laser 10 has a structure in which the above-described first mirror 11, the active layer 12 and the second mirror 13 are sequentially laminated on the semiconductor substrate SB. The first mirror 11 and the second mirror 13 are distributed reflection type multilayer mirrors each composed of alternately laminated three-element mixed crystal semiconductors of mutually different compositions. The first mirror is, for example, a distributed reflection type multilayer mirror of 25 pairs of alternately laminated n-type Al_{0.15}Ga_{0.85}As layers (hereafter referred to as “lower composition layers”) and n-type Al_{0.9}Ga_{0.1}As layers (hereafter referred to as “higher composition layers”). Graded index layers (GI layers), in which the Al composition is gradually changed, are formed between the low composition layers and the high composition layers, respectively, in a portion of the first mirror 11. Details thereof are described below.

It is noted that, in the present embodiment, the lower composition layer means an AlGaAs layer with an aluminum (Al) composition being lower than a gallium (Ga) composition, and the higher composition layer means an AlGaAs layer with an aluminum (Al) composition being higher than a gallium (Ga) composition. The Al composition in an AlGaAs layer ranges from 0 to 1. In other words, an AlGaAs layer includes a GaAs layer (when the Al composition is 0) and an AlAs layer (when the Al composition is 1). Also, the composition of each of the layers and the number of the layers forming the first mirror 11, the active layer 12 and the second mirror 13 are not particularly limited to the above. It is noted that the Al composition of the topmost layer of the second mirror 13 may preferably be less than 0.3.

The active layer 12 is formed on the first mirror 11, and is composed of GaAs well layers and Al_{0.3}Ga_{0.7}As barrier layers in which the well layers include a quantum well structure composed of three layers. The second mirror 13 is formed on the active layer 12, and is a distributed reflection type multilayer mirror of 25 pairs of alternately laminated p-type Al_{0.15}Ga_{0.85}As layers (hereafter referred to as lower composition layers) and p-type Al_{0.9}Ga_{0.1}As layers (hereafter referred to as higher composition layers). It is noted that the second mirror 13 at its topmost layer is formed to be a layer with a smaller Al composition, in other words, a p-type Al_{0.15}Ga_{0.85}As layer. Between the lower composition layers and the higher composition layers forming the second mirror 13, composition graded index layers (GI layers) whose Al composition is gradually changed are formed which are described in greater detail below.

The first mirror 11 composing the surface-emitting type semiconductor laser 10 is formed to be n-type by doping, for example, silicon (Si), and the second mirror 13 is formed to be p-type by doping, for example, carbon (C). Accordingly, the p-type second mirror 13, the active layer 12 in which no impurity is doped, and the n-type first mirror 11 form a pin diode.

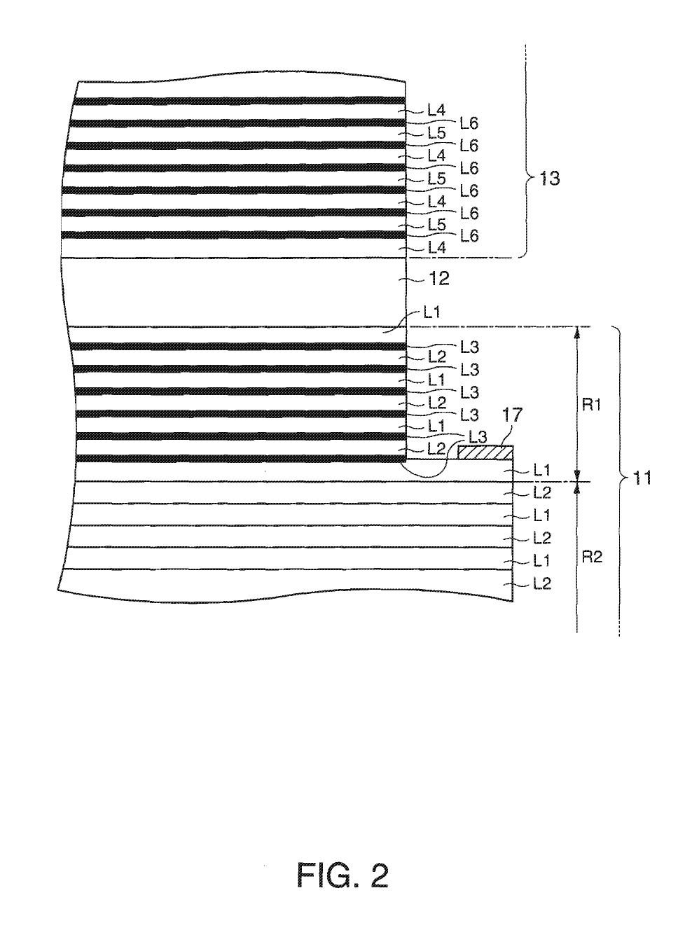

Next, the first mirror 11 and the second mirror 13 are described in greater detail. FIG. 2 is an enlarged cross-sectional view of the first mirror 11 and the second mirror 13 near the active layer 12. As shown in FIG. 2, the first mirror 11 may be generally divided into a first region R1 that is in contact with the active layer 12, and a second region R2 located below the first region R1. The first region R1 is a region where low composition layers L1 and high composition layers L2 are alternately laminated, and GI layers L3 with Al composition being gradually changed are formed between the low composition layers L1 and the high composition layers L2, respectively. The second region R2 is a region where low composition layers L1 and high composition layers L2 are alternately laminated, and GI layers are not formed between the low composition layers L1 and the high composition layers L2 like the first region R1.

Also, the second mirror 13 is not divided into multiple regions like the first mirror 11, and has low composition layers L4 and high composition layers L5 alternately laminated through its entire length, wherein GI layers L6 are formed between the low composition layers L4 and the high composition layers L5, respectively. In other words, the second mirror 13 has a structure in its entirety similar to that of the first region R1 of the first mirror 11. It is noted that the high composition layers L1 and the low composition layers L2 formed in the first mirror 11, and the high composition layers L4 and the low composition layers L5 formed in the second mirror 13 are each formed to have an optical film thickness of λ/4. It is noted that λ is a wavelength of laser light of the surface-emitting type semiconductor laser 10.

Each of the GI layers L3 and L6 formed respectively in the first region R1 of the first mirror 11 and the second mirror 13 is a layer whose Al composition is gradually changed between 0.15 and 0.9, such that the energy barrier at an interface between the low composition layer L1 and the high composition layer L2 and the energy barrier at an interface between the low composition layer L4 and the high composition layer L5 are smoothed, to thereby lower the resistance. It is noted that, because a change in the Al composition causes a change in the refractive index, the refractive index gradually changes in a portion where the GI layers L3 and L6 are formed. As shown in FIGS. 1 and 2, electrodes 17 and 18 for driving the surface-emitting type semiconductor laser 10 are formed on the low composition layer L1 in the first region R1 of the first mirror 11 and on the second mirror 13, respectively, such that electrical current hardly flows in the second region R2 of the first mirror 11.

The GI layers L3 in the first region R1 of the first mirror 11 are provided to reduce the resistance of the first mirror 11, and the GI layers L6 in the second mirror 13 are provided to reduce the resistance of the second mirror 13. However, as described above, the GI layer L3 formed between the low composition layer L1 and the high composition layer L2 causes the refractive index to gradually change, and the GI layer L6 formed between the low composition layer L4 and the high composition layer L5 causes the refractive index to gradually change. It is desirable that the refractive index steeply change between the low composition layer L1 and the high composition layer L2 in order to provide the first mirror 11 with a high reflection coefficient. For this reason, in accordance with the present embodiment, the second region R2 where almost no electric current flows is provided with a structure in which GI layers are not provided between the low composition layers L1 and the high composition layers L2, thereby increasing the reflection coefficient of the first mirror 11.

It is noted that the first pair of the low composition layer L1 and the high composition layer L2 formed at the topmost layer of the first mirror 11 through around the fifth pair may preferably be included in the first region R1. To reduce the resistance of the surface-emitting type semiconductor laser 10, it is desirable that the low composition layer L1 in contact with the electrode 17 be placed in proximity to the active layer 12 as close as possible. As described above, because the surface-emitting type semiconductor laser 10 of the present embodiment has a structure in which a portion thereof is included in the columnar section P1, stress would likely be concentrated at the base portion of the columnar section P1, and therefore the base portion would likely be deteriorated.

As shown in FIG. 1 and FIG. 2, the low composition layer L1 that is in contact with the electrode 17 is disposed at the base portion of the columnar section P1. When the low composition layer L1 and the active layer 12 are too close to each other, deterioration of the characteristics of the surface-emitting type semiconductor laser 10 would likely occur. On the other hand, if the low composition layer L1 (or the high composition layer L2) that is in contact with the electrode 17 is formed at a position too far away from the active layer 12, the resistance becomes greater despite that the aforementioned GI layers L3 may be formed. Accordingly, by including the first pair formed at the topmost layer of the first mirror 11 through around the fifth pair in the first region R1, the resistance can be reduced, and the aforementioned deterioration can be prevented.

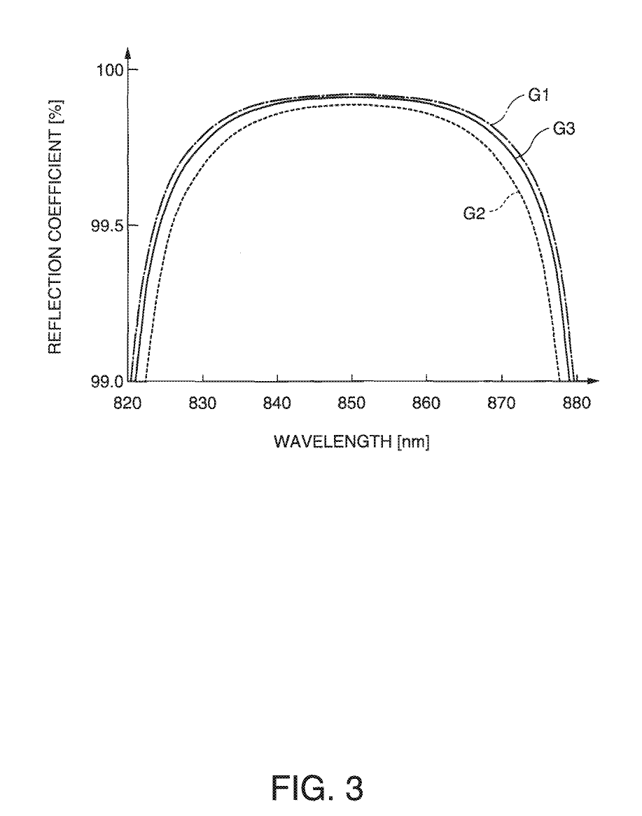

Changes in the reflection coefficient when GI layers are formed and when GI layers are not formed are described. FIG. 3 is a graph showing changes in the reflection coefficient due to the presence or absence of the GI layers. It is noted that the graph in FIG. 3 plots wavelengths along the axis of abscissas and reflection coefficients along the axis of ordinates. In FIG. 3, a curve in a dot-and-dash line appended by a sign G1 indicates changes in the reflection coefficient with respect to wavelengths when 25 pairs of low composition layers and high composition layers are provided, and GI layers are not formed.

Also, a curve in a broken line appended by a sign G2 indicates changes in the reflection coefficient with respect to wavelengths when 25 pairs of low composition layers and high composition layers are provided, and GI layers are formed between the low composition layers and the high composition layers, respectively. Furthermore, a curve in a solid line appended by a sign G3 indicates changes in the reflection coefficient with respect to wavelengths when 25 pairs of low composition layers and high composition layers are provided, and GI layers are formed among 5 pairs out of the 25 pairs of low composition layers and high composition layers. In other words, the curve G2 indicates changes in the reflection coefficient of the second mirror 13 with respect to wavelengths, and the curve G3 indicates changes in the reflection coefficient of the first mirror 11 with respect to wavelengths.

In comparing the curve G1 with the curve G2, it is observed that the reflection coefficient lowers and the wavelength region in which high reflection coefficient (about 99.9%) can be obtained becomes narrower when the GI layers are formed among the 25 pairs of low composition layers and high composition layers, compared to the case where GI layers are not formed at all. When the reflection coefficient lowers, the oscillation threshold of the surface-emitting type semiconductor laser 10 would likely elevate. Also, when the wavelength region where high reflection coefficient can be obtained becomes narrower, the design margin of the surface-emitting type semiconductor laser 10 becomes narrower which may cause a lowered yield.

Next, referring to the curve G3, when GI layers are formed among only 5 pairs out of the 25 pairs of low composition layers and high composition layers, it is observed that reflection coefficients generally the same as those of the case where GI layers are not formed at all can be obtained, although the reflection coefficient slightly lowers as compared to the case where GI layers are not formed at all. Also, the wavelength region of the curve G3 in which high reflection coefficient can be obtained is generally the same as that of the curve G1. As described above, considering the stress concentration at the base portion of the columnar section P1 and the changes in the reflection coefficient described above, the first pair formed at the topmost layer of the first mirror 11 through about the fifth pair may preferably be included in the first region R1.

Returning to FIG. 1, a portion among the surface-emitting type semiconductor laser 10 extending from the second mirror 13 to an inner point of the first mirror 11 in the first region R1 is etched in a circular shape, as viewed from an upper surface of the second mirror 13, thereby forming a columnar section P1. It is noted that the present embodiment is described as to a case in which the columnar section P1 has a plane configuration that is circular, but its configuration can have any other arbitrary configurations.

Furthermore, a current constricting layer 15, which is obtained by oxidizing the AlGaAs layer from its side surface, is formed in a region near the active layer 12 among the layers composing the second mirror 13. The current constricting layer 15 is formed in a ring shape. In other words, the current constricting layer 15 has a cross section, when cut in a plane parallel with a surface of the semiconductor substrate SB, which is a circular ring shape concentric with a circular shape of the plane configuration of the columnar section P1.

In the surface-emitting type semiconductor laser 10 of the present embodiment, an insulation layer 16 is provided on the first mirror 11 (on the low composition layer L1 exposed around the columnar section P1) in a manner to surround the circumference of the columnar section P1. By surrounding the circumference of the columnar section P1 with the insulation layer 16, oxidation of the layers composing the columnar section P1 can be prevented, such that the reliability of the surface-emitting type semiconductor laser 10 can be improved. The insulation layer 16 may have a film thickness of, for example, about 2-4 μm, and can be formed from material that is obtained by hardening liquid material settable by energy, such as, heat, light or the like (for example, a precursor of ultraviolet setting type resin or thermosetting type resin). As the ultraviolet setting type resin, for example, an ultraviolet setting type acrylic resin, epoxy resin or the like can be enumerated. Also, as the thermosetting type resin, a thermosetting type polyimide resin or the like can be enumerated.

An electrode 17 is formed on the first mirror 11 (on the low composition layer L1 exposed around the columnar section P1), and an electrode 18 is formed on the second mirror 13. The electrode 17 is bonded and electrically connected to an upper surface of the first mirror 11 (on the low composition layer L1 exposed around the columnar section P1). It is noted that the electrode 17 is connected to a pad section (not shown). It is noted that the present embodiment is described as to the case as an example where the electrode 17 is formed on the low composition layer L2 exposed around the columnar section P1. However, if the high composition layer L1 is exposed around the columnar section P1, the electrode 17 may be formed on the high composition layer L2.

The electrode 18 has a connecting section 18a having a ring-shaped plane configuration that defines an opening at a central portion of the second mirror 13, and a lead-out section 18b that connects the connecting section 18a to a pad section (not shown) (which is different from the aforementioned pad section connected to the electrode 17). The connection section 18a is bonded and electrically connected to the upper surface of the second mirror 13. It is noted that the upper surface of the second mirror 13 defines a laser light emission surface 19. The lead-out section 18b is formed on the insulation layer 16 and extends to the pad section (not shown).

The electrode 17 is composed of, for example, a laminated film of an alloy of gold (Au) and germanium (Ge), and gold (Au), and is in ohmic contact with the low composition layer L1 exposed around the columnar section P1. Also, the electrode 18 is composed of, for example, a laminated film of platinum (Pt), titanium (Ti) and gold (Au), and is in ohmic contact with the top surface of the second mirror 13. These electrodes 17 and 18 are used to drive the surface-emitting type semiconductor laser 10, and electric current is injected in the active layer 12 by the electrode 17 and the electrode 18. It is noted that the materials for forming the electrode 17 and the electrode 18 are not limited to those described above, and, for example, an alloy of gold (Au) and zinc (Zn) can be used.

Next, general operations of the surface-emitting type semiconductor laser 10 of the present embodiment are described below. It is noted that the following method for driving the surface-emitting type semiconductor laser 10 is described as an example, and various changes can be made within the scope of the invention. First, when a voltage in a forward direction is applied to the pin diode across the electrode 17 and the electrode 18 that are connected to a power supply (not shown), holes flow in the active layer 12 from the electrode 18 through the second mirror 13, and electrons flow in the active layer 12 from the electrode 17 through the low composition layer L1 included in the region R1 of the first mirror 11. Recombination of electrons and holes occur in the active layer 12 of the surface-emitting type semiconductor laser 10, thereby causing emission of light due to the recombination. Stimulated emission occurs during the period the generated light reciprocates between the second mirror 13 and the first mirror 11, whereby the light intensity is amplified. When the optical gain exceeds the optical loss, laser oscillation occurs, whereby laser light is emitted from the top surface (the emission surface 19) of the second mirror 13.

Method for Manufacturing Surface-Emitting Type Semiconductor Laser

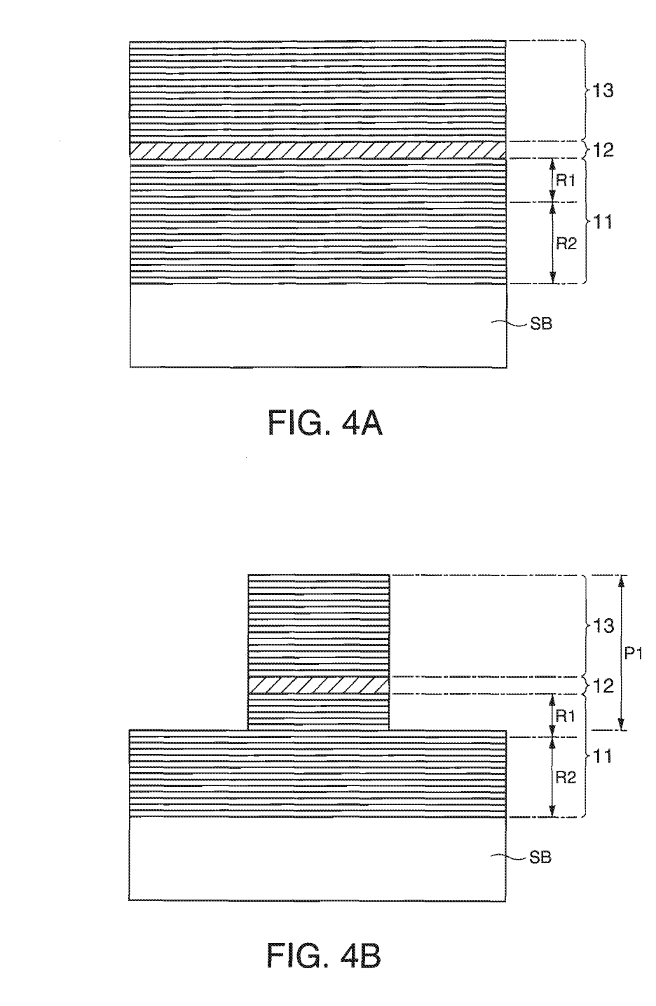

Next, a method for manufacturing the surface-emitting type semiconductor laser 10 described above is described. FIGS. 4-6 are cross-sectional views schematically showing a process of manufacturing the surface-emitting type semiconductor laser in accordance with an embodiment of the invention. It is noted that these drawings correspond to the cross-sectional view shown in FIG. 1, respectively. To manufacture the surface-emitting type semiconductor laser 10 of the present embodiment, first, as shown in FIG. 4A, on a semiconductor substrate SB composed of an n-type GaAs layer, a semiconductor multilayered film is formed by epitaxial growth while modifying their composition.

The semiconductor multilayered film is composed of a first mirror 11, an active layer 12 and a second mirror 13. The first mirror 11 may be formed by alternately laminating n-type Al_{0.15}Ga_{0.85}As layers (low composition layers L1) and n-type Al_{0.9}Ga_{0.1}As layers (high composition layers L2) in about 20 pairs to thereby form a second region R2. The low composition layers L1 and the high composition layers L2 are each formed to have an optical film thickness of λ/4. Next, a first region R1 is formed on the second region R2 composed of the laminated low composition layers L1 and high composition layers L2. Concretely, the low composition layers L1, the GI layers L3 and the high composition layers L2 are sequentially laminated in about 5 pairs. It is noted that the low composition layers L1 and the high composition layers L2 in the first region R1 are also each formed to have an optical film thickness of λ/4.

The active layer 12 is composed of, for example, GaAs well layers and Al_{0.3}Ga_{0.7}As barrier layers in which the well layers include a quantum well structure composed of three layers. The second mirror 13 is formed by alternately laminating p-type Al_{0.15}Ga_{0.85}As layers (low composition layers L4), GI layers L6, and p-type Al_{0.9}Ga_{0.1}As layers (high composition layers L5) in about 25 pairs. The low composition layers L4 and the high composition layers L5 forming the second mirror 13 are also each formed to have an optical film thickness of λ/4. The topmost layer of the second mirror 13 is one of the low composition layer L4.

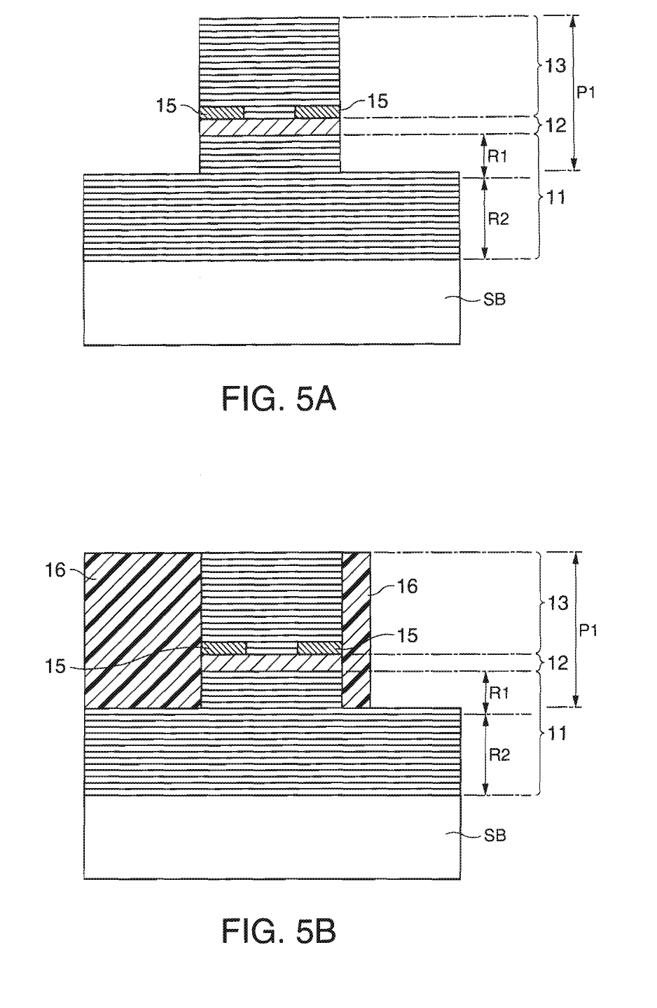

It is noted that, when the second mirror 13 is grown, at least one layer thereof near the active layer 12 is formed to be a layer that is later oxidized and becomes a current constricting layer 15 (see FIG. 5A). For this reason, the layer that becomes to be the current constricting layer 15 is formed to be an AlGaAs layer (including an AlAs layer) having a greater Al composition. For example, the layer that becomes to be the current constricting layer 15 may preferably be formed such that its Al composition becomes to be 0.95 or greater.

Also, when an electrode 18 is formed in a later step, at least a portion of the second mirror 13 that is in contact with the electrode 18 may preferably be formed with a high carrier density such that ohmic contact can be readily made with the electrode 18, and may be provided with a property to have greater adhesion with the electrode 18. Similarly, among the low composition layers L1 included in the first region R1 of the second mirror 11, one of the low composition layers L1 that is to be later in contact with the electrode 17 may preferably be formed with carrier density higher than that of the other low composition layers L1 such that ohmic contact can be readily made with the electrode 17, and greater adhesion with the electrode 17 can be achieved.

The temperature at which the epitaxial growth is conducted is appropriately decided depending on the growth method, the kind of raw material) the type of the semiconductor substrate SB, and the kind, thickness and carrier density of the semiconductor multilayer film to be formed, and may preferably be set generally at 450° C.-800° C. Also, the time required for conducting the epitaxial growth is appropriately decided like the temperature. Also, a metal-organic vapor phase deposition (MOVPE: Metal-Organic Vapor Phase Epitaxy) method, a MBE method (Molecular Beam Epitaxy) method or a LPE (Liquid Phase Epitaxy) method can be used as a method for the epitaxial growth.

Next, as shown in FIG. 4B, a columnar section P1 is formed. For forming the columnar section P1, first, resist (not shown) is coated on the semiconductor multilayer film, and then the resist is patterned by a lithography method. As a result, a resist layer having a specified plane configuration is formed on the upper surface of the second mirror 13. Then, by using the resist layer as a mask, the second mirror 13, the active layer 12 and the first mirror 11 to a point inside the first region R1 are etched by, for example, a dry etching method. More concretely, etching is conducted down to one of the high composition layers L2 (see FIG. 2) located on the low composition layer L1 having higher carrier density than that of the other low composition layers L1 among the low composition layers L1 included in the first region R1.

While etching is conducted by a dry etching method, the intensity of emission spectra caused by at least one of aluminum (Al) and gallium (Ga) contained in the plasma is monitored. Then, the amount of etching is controlled based on the monitored result. By this, the second mirror 13, the active layer 12 and an upper portion of the first mirror 11 are formed to have the same plane configuration in a columnar section P1. It is noted that, when the columnar section P1 is formed, the resist layer is removed.

When the columnar section P1 is formed, a current constricting layer 15 is formed, as shown in FIG. 5A. To form the current constricting layer 15, the semiconductor substrate SB on which the columnar section P1 is formed through the aforementioned steps is placed in a water vapor atmosphere at, for example, about 400° C. As a result, a layer having a high Al composition in the second mirror 13 described above is oxidized from its side surface, whereby the current constricting layer 15 is formed.

The oxidation rate depends on the temperature of the furnace, the amount of water vapor supply, and the Al composition and the film thickness of the layer to be oxidized. In a surface-emitting type laser equipped with the current constricting layer 15 that is formed by oxidation, current flows only in a portion where the current constricting layer 15 is not formed (a portion that is not oxidized). Accordingly, in the process of forming the current constricting layer 15, the range of the current constricting layer 15 to be formed may be controlled, whereby the current density can be controlled.

Next, as shown in FIG. 5B, an insulation layer 16 is formed on the low composition layer L1 exposed around the columnar section P1. The insulation layer 16 may preferably be composed of a material that is easier to make a thick film. The film thickness of the insulation layer 16 may be, for example, about 2-4 μm, but it is not particularly limited. For example, the insulation layer 16 can be formed from material that is obtained by hardening liquid material settable by energy, such as, heat, light or the like (for example, a precursor of ultraviolet setting type resin or thermosetting type resin). As the ultraviolet setting type resin, for example, an ultraviolet setting type acrylic resin, epoxy resin or the like can be enumerated. Also, as the thermosetting type resin, a thermosetting type polyimide resin or the like can be enumerated. Furthermore, for example, the insulation layer 16 may be composed of a laminated layered film using a plurality of the materials described above.

In this embodiment, the case where a precursor of polyimide resin is used as the material for forming the insulation layer 16 is described. First, for example, by using a spin coat method, the precursor (precursor of polyimide resin) is coated on the first mirror 11 (on the low composition layer L1 exposed around the columnar section P1), thereby forming a precursor layer. It is noted that, as the method for forming the precursor layer, besides the aforementioned spin coat method, another known technique, such as, a dipping method, a spray coat method, a liquid ink jet method or the like can be used. Then, the semiconductor substrate SB is heated by using, for example, a hot plate or the like, thereby removing the solvent, and then is placed in a furnace at about 350° C. to thereby imidize the precursor layer, whereby a polyimide resin layer that is almost completely set is formed. Then, the polyimide resin layer is patterned by using a known lithography technique, thereby forming the insulation layer 16.

As the etching method used for patterning, a dry etching method or the like can be used. Dry etching can be conducted with, for example, oxygen or argon plasma. In the method for forming the insulation layer 16 described above, an example in which a precursor layer of polyimide resin is hardened and then patterning is conducted is described. However, before hardening the precursor layer of polyimide resin, patterning may be conducted. As the etching method used for this patterning, a wet etching method or the like may be used. The wet etching may be conducted with, for example, an alkaline solution or an organic solution.

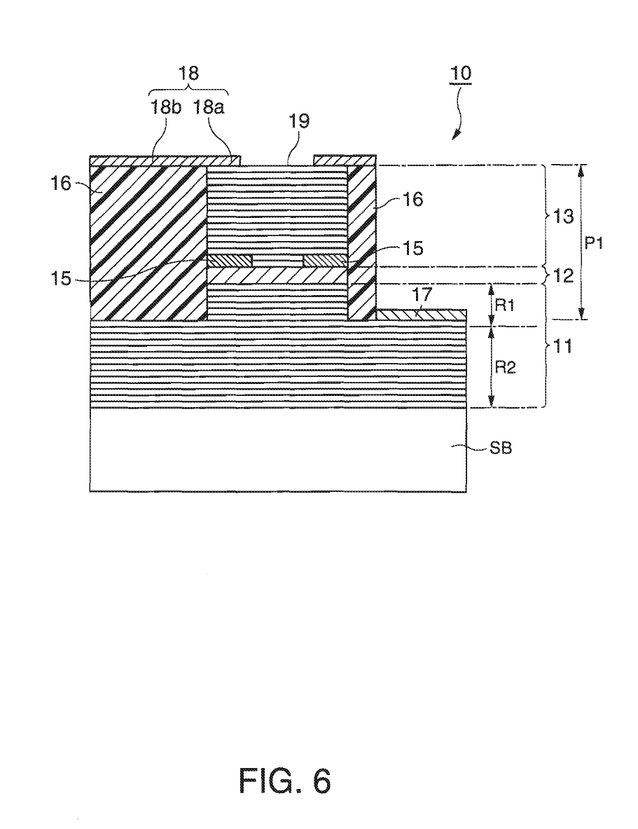

When the steps described above are completed, an electrode 17 is formed on the top surface of the first mirror 11 (on the low composition layer L1 exposed around the columnar section P1), and an electrode 18 is formed on the top surface of the second mirror 13, as shown in FIG. 6. As described above, the electrode 18 includes a connecting section 18a having a ring-shaped plane configuration and a lead-out section 18b having a linear plane configuration. It is noted that the connecting section 18a is formed on the top surface of the second mirror 13, and the lead-out section 18b is formed on the insulation layer 16.

In accordance with an exemplary method, the electrode 18 may be formed as follows. First, before the electrode 18 is formed, a top surface of the second mirror 13 may be washed by a plasma processing method or the like, if necessary. As a result, an element with more stable characteristics can be formed. Next, a laminated film (not shown) of platinum (Pt), titanium (Ti), and gold (Au), for example, is formed by, for example, a vacuum deposition method. Then, the electrode 18 is formed by removing the laminated film other than specified positions by a lift-off method.

In this instance, a portion where the laminated film is not formed is formed on the top surface of the second mirror 13. This portion defines an opening section, and a portion of the top surface of the second mirror 13 is exposed through the opening section. The exposed surface defines an emission surface 19 for emitting laser light. It is noted that a dry etching method or a wet etching method can be used in the above-described process instead of the lift-off method. Also, in the process described above, a sputter method can be used instead of the vacuum deposition method.

Next, by a similar method used in forming the electrode 18, a laminated film of, for example, an alloy of gold (Au) and germanium (Ge), and gold (Au) is patterned, whereby an electrode 17 is formed on the first mirror 11 (on the low composition layer L1 exposed around the columnar section P1), as shown in FIG. 6. Then, an annealing treatment is conducted. The temperature of the annealing treatment depends on the electrode material. This is usually conducted at about 400° C. for the electrode material used in the present embodiment. The electrodes 17 and 18 are formed by the process described above. By the process described above, the surface-emitting type semiconductor laser 10 shown in FIG. 1 in accordance with the present embodiment is manufactured.

As described above, in the surface-emitting type semiconductor laser 10 of the present embodiment, the GI layers L3 are formed between the low composition layers L1 and the high composition layers L2 laminated in the first region of the first mirror 11 in contact with the active layer 12, and the columnar section P1 is formed by etching the second mirror 13, the active layer 12 and the first mirror 11 to an inner portion of the first region R1. Also, in the second mirror 13, the GI layers L6 are formed between the low composition layers L4 and the high composition layers L5, respectively. Further, the electrode 17 is formed on the first mirror 11 exposed by etching (on the low composition layer L1 exposed around the columnar section P1), and the electrode 18 is formed on the second mirror 13. As a result, energy barriers at interfaces of the laminated semiconductor layers of different types are hardly present on the current flow path through the electrodes 17 and 18, such that the resistance in the surface-emitting type semiconductor laser can be reduced.

Also, in the second region R2 of the first mirror 11, the low composition layers L1 and the high composition layers L2 are alternately laminated, and GI layers L3 are not formed between the low composition layers L1 and the high composition layers L2 like the first region R1, such that the reflection coefficient steeply changes between the low composition layers L1 and the high composition layers L2 in the second region R2. For this reason, in accordance with the present embodiment, the second region R2 where electrical current hardly flows can have a higher reflection coefficient, such that a substantial reduction in the reflection coefficient of the first mirror 11, which may be caused by the GI layers L3 formed in the first region R1, can be prevented. As a result, an elevation in the oscillation threshold of the surface-emitting type semiconductor laser 10 can be suppressed.

Other Embodiments

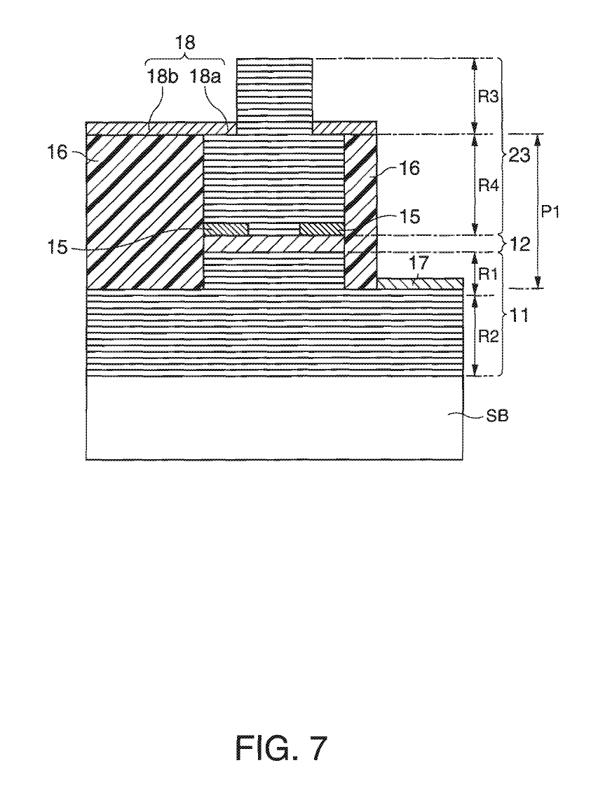

Next, another embodiment of the invention is described. FIG. 7 is a schematic cross-sectional view of a surface-emitting type semiconductor laser in accordance with another embodiment of the invention. It is noted that, in FIG. 7, members identical with those shown in FIG. 1 are appended with the same reference numbers. As shown in FIG. 7, the surface-emitting type semiconductor laser 20 in accordance with the present embodiment is formed on a semiconductor substrate (an n-type GaAs substrate in the present embodiment) SB, and includes a first mirror 11, an active layer 12 and a second mirror 23.

As shown in FIG. 7, the first mirror 11 of the surface-emitting type semiconductor laser 20 of the present embodiment is the same as that of the surface-emitting type semiconductor laser 10 shown in FIG. 1. More specifically, the first mirror 11 is generally divided into a first region R1 that is in contact with the active layer 12, and a second region R2 located below the first region R1. The first region R1 includes low composition layers L1 and high composition layers L2 alternately laminated, and GI layers L3 with Al composition being gradually changed formed between the low composition layers L1 and the high composition layers L2, respectively. The second region R2 includes low composition layers L1 and high composition layers L2 alternately laminated. Further, the active layer 12 of the surface-emitting type semiconductor laser 20 in accordance with the present embodiment is the same as that of the surface-emitting type semiconductor laser 10 shown in FIG. 1.

A mirror (a second mirror 23) formed on the active layer 12 of the surface-emitting type semiconductor laser 20 of the present embodiment has a structure different from the structure of the second mirror 13 of the surface-emitting type semiconductor laser 10 shown in FIG. 1. The second mirror 23 of the surface-emitting type semiconductor laser 20 of the present embodiment is generally divided into a fourth region R4 that is in contact with the active layer 12 and a third region R3 located above the fourth region R4. The fourth region R4 is a region where low composition layers L4 and high composition layers L5 are alternately laminated, and GI layers L6 with Al composition being gradually changed are formed between the low composition layers L4 and the high composition layers L5, respectively. In other words, the fourth region R4 has a mirror having the same structure as that of the second mirror 13 shown in FIG. 1.

In contrast, a mirror composed of a dielectric multilayer film is formed in the third region R3. As described above, the GI layers L6 are formed between the low composition layers L4 and the high composition layers L5 in the fourth region R4 of the second mirror 23, the reflection coefficient of the second mirror 23 lowers. In order to compensate for the reduction of the reflection coefficient, the mirror composed of dielectric multilayer film is formed in the third region R3. The mirror formed in the third region R3 may be a dielectric multilayer film of, for example, SiO₂ and TiO₂ layers, whose pair number is determined according to a reflection coefficient required by the second mirror 23.

Also, as shown in FIG. 7, the third region R3 of the second mirror 23 is formed in a columnar configuration having a diameter smaller than that of the columnar section P1. Because the electrode 18 is formed around the third region R3, it can be said that the surface-emitting type semiconductor laser 20 of the present embodiment is equivalent to the surface-emitting type semiconductor laser 10 shown in FIG. 1 with the mirror composed of dielectric multilayer film (the third region R3) formed on the laser light emission surface 19. The surface-emitting type semiconductor laser 20 of the present embodiment having the structure described above can further suppress an elevation of the oscillation threshold, because the second mirror 23 can have a higher reflection coefficient compared to that of the surface-emitting type semiconductor laser 10 shown in FIG. 1.

Embodiments of the invention are described above. However, the invention is not limited to the embodiments described above, and can be freely modified within the scope of the invention. For example, in the surface-emitting type semiconductor laser 10 shown in FIG. 1, only the first mirror 11 is divided into the first region R1 and the second region R2, wherein low composition layers L1, high composition layers L2 and GI layers L3 between the low composition layers L1 and the high composition layers L2 are laminated in the first region R1 that is in contact with the active layer 12, and low composition layers L1 and high composition layers L2 are laminated in the second region R2.

Also, in the surface-emitting type semiconductor laser 20 shown in FIG. 7, the first mirror 11 is divided into the first region R1 and the second region R2, like the surface-emitting type semiconductor laser 10 shown in FIG. 1. On the other hand, the second mirror 23 is divided into the third region R3 and the fourth region R4, wherein low composition layers L4, high composition layers L5 and GI layers L6 between the low composition layers L4 and the high composition layers L5 are laminated in the fourth region R4 that is in contact with the active layer 12, and the dielectric multilayer film is formed in the third region R3.

However, only the second mirror 13 may be divided into two regions like the forgoing exemplary embodiment. When two regions are to be formed only in the second mirror 13, low composition layers L4, high composition layers L5 and GI layers L6 between the low composition layers L4 and the high composition layers L5 may be laminated in a region that is in contact with the active layer 12, and in a region located above the aforementioned region may be provided with a structure in which low composition layers L4 and high composition layers L5 are laminated.

In such a structure, only the second mirror 13 may be formed in a columnar configuration, and a low composition layer L4 (or a high composition layer L5) in the region where the GI layers L6 are formed may preferably be connected to an electrode corresponding to the electrode 18. Also, in such a structure, the entire first mirror 11 may be provided with a structure in which low composition layers L1, high composition layers L2 and GI layers L3 between the low composition layers L1 and the high composition layers L2 are laminated, and an electrode corresponding to the electrode 17 may preferably be connected to a bottom surface of the first mirror 11 (a bottom surface of the first mirror 11 that is exposed as a result of removal of the substrate SB).

Furthermore, in such a structure, a mirror similar to the mirror composed of the dielectric multilayer film formed in the third region R3 of the second mirror 23 shown in FIG. 7 may preferably be formed at the bottom surface of the first mirror 11 that is exposed when the substrate SB is removed at a position below the columnar section P1. By forming such a mirror, a reduction in the reflection coefficient of the first mirror 11 can be prevented.

Also, in the embodiments described above, the first mirror 11 and the second mirror 13 are formed with AlGaAs layers of mutually different Al compositions. However, the invention is not limited to AlGaAs layers, and it is also applicable to surface-emitting type semiconductor lasers in which a first mirror 11 and a second mirror 13 are formed with layers of other kinds of semiconductor. Moreover, in the embodiments described above, interchanging the p-type and n-type characteristics of each of the semiconductor layers does not deviate from the subject matter of the present invention.

Furthermore, the surface-emitting type semiconductor laser 10 in accordance with the embodiment described above has a structure in which the columnar section P1 is formed. However, the surface-emitting type semiconductor laser in accordance with the invention may not need to have such a structure. For example, the surface-emitting type semiconductor laser may be provided with a structure in which bores reaching from the second mirror 13 to the upper portion of the first mirror 11 may be formed at several locations around the emission surface for emitting laser light. It is noted that the bores are used for forming a current constricting layer.

What is claimed is:

1. A surface-emitting type semiconductor laser comprising:
an upper mirror;
a lower mirror; and
an active layer disposed between the upper mirror and the lower mirror, which emits laser light in a direction of lamination of the lower mirror, the active layer and the upper layer,
wherein at least one of the upper mirror and the lower mirror includes
a first region which is in contact with the active layer and is formed with a first semiconductor layer having a first refractive index, a second semiconductor layer having a second refractive index, and a third semiconductor layer provided between the first semiconductor layer and the second semiconductor layer and having a refractive index between the first refractive index and the second refractive index
a second region formed with the first semiconductor layer and the second semiconductor layer.

2. A surface-emitting type semiconductor laser according to claim 1, wherein a plurality of the first semiconductor layers and the second semiconductor layers are formed in the first region, and the third semiconductor layer is formed at each of interfaces between the first semiconductor layers and the second semiconductor layers.

3. A surface-emitting type semiconductor laser according to claim 1, wherein at least one of the upper mirror and the lower mirror is quipped with a third region having a mirror composed of a dielectric multilayer film.

4. A surface-emitting type semiconductor laser according to claim 3, comprising an electrode that is in contact with one of the first semiconductor layer and the second semiconductor layer composing the first region and supplies electric current to the active layer.

5. A surface-emitting type semiconductor laser according to claim 4, wherein the one of the first semiconductor layer and the second semiconductor layer that is in contact with the electrode has an impurity concentration higher than an impurity concentration of the other semiconductor layer.

6. A surface-emitting type semiconductor laser according to claim 4, wherein the electrode includes a first electrode provided at the first region of the upper mirror, and a second electrode provided at the first region of the lower mirror.

7. A surface-emitting type semiconductor laser according to claim 6, wherein the second electrode contacts one of the first semiconductor layer and the second semiconductor layer forming one of a first pair through a fifth pair of the first semiconductor layer and the second semiconductor layer, the first pair being formed at an uppermost layer of the lower mirror.

8. A surface-emitting type semiconductor laser according to claim 6, wherein the upper mirror, the active layer and at least a part of the first region provided in the lower mirror are formed in a columnar configuration defining a columnar section.

9. A surface-emitting type semiconductor laser according to claim 8, wherein the semiconductor layers of the lower mirror located above the semiconductor layer that is in contact with the second electrode are formed in the columnar section.

10. A surface-emitting type semiconductor laser according to claim 1, wherein the first semiconductor layer and the second semiconductor layer is composed of mixed crystal semiconductors of different compositions.

11. A surface-emitting type semiconductor laser according to claim 10, wherein the first semiconductor layer is composed of mixed crystal semiconductor with a low composition than the second semiconductor layer.

12. A method for manufacturing a surface-emitting type semiconductor laser including an upper mirror, a lower mirror and an active layer disposed between the upper mirror and the lower mirror, which emits laser light in a direction of lamination of the lower mirror, the active layer and the upper layer, the method comprising, in forming the upper mirror and the lower mirror, the steps of:
forming, in at least one of the upper mirror and the lower mirror, a first region that is in contact with the active layer and includes a first semiconductor layer having a first refractive index, a second semiconductor layer having a second refractive index, and a third semiconductor layer provided between the first semiconductor layer and the second semiconductor layer and having a refractive index between the first refractive index and the second refractive index; and
forming a second region with the first semiconductor layer and the second semiconductor layer alternately laminated in a region other than the first region.

13. A method for manufacturing a surface-emitting type semiconductor laser according to claim 12, comprising the step of forming a third region having a mirror composed of a dielectric multilayer film in at least one of the upper mirror and the lower mirror.

14. A method for manufacturing a surface-emitting type semiconductor laser according to claim 12, comprising the step of etching the upper mirror, the active layer and the lower mirror to an inside of the first region formed in the lower mirror to form a columnar section composed of the upper mirror, the active layer and at least a portion of the lower mirror in a columnar configuration.

15. A method for manufacturing a surface-emitting type semiconductor laser according to claim 14, wherein the first semiconductor layer and the second semiconductor layer are composed of mixed crystals of different compositions, and when the upper mirror, the active layer and a portion of the first region formed in the lower mirror are etched, the amount of etching is controlled while monitoring changes in the compositions.
